(19) United States
(12) Patent Application Publication
(10) Pub. No.: US 2008/0218219 A1
(43) Pub. Date: Sep. 11, 2008

(54) COMPARATOR AND IMAGE DISPLAY SYSTEM

(76) Inventor: Ping-Lin LIU, Tainan City (TW)

Correspondence Address: BIRCH STEWART KOLASCH & BIRCH, PO BOX 747, FALLS CHURCH, VA, 22040-0747, US

(21) Appl. No.: 12/040,342

(22) Filed: Feb. 29, 2008

(30) Foreign Application Priority Data
Mar. 7, 2007 (TW) 096107811

(51) Int. Cl. H03K 5/22; G09G 3/20

(52) U.S. Cl. 327/77; 345/55

(57) ABSTRACT

A comparator for comparing a reference signal with a data signal includes a voltage boosting circuit, a first logic inverting circuit and a second logic inverting circuit. The voltage boosting circuit receives the reference signal to hold a voltage difference during a first time, and receives the data signal to generate a comparing signal according to the data signal and the voltage difference during a second time. The first logic inverting circuit is electrically connected to the voltage boosting circuit, outputs an initial signal to the voltage boosting circuit to hold the voltage difference during the first time, and inverts the comparing signal to output a first voltage signal during the second time. The second logic inverting circuit is electrically connected to the first logic inverting circuit during the second time, and inverts the first voltage signal to output a second voltage signal fed back to hold the comparing signal.

### CROSS REFERENCE TO RELATED APPLICATIONS

This Non-provisional application claims priority under 35 U.S.C. §119(a) on Patent Application No(s). 096107811 filed in Taiwan, Republic of China on Mar. 7, 2007, the entire contents of which are hereby incorporated by reference.

### BACKGROUND OF THE INVENTION

1. Field of Invention

The invention relates to a comparator capable of stably and precisely outputting a comparing result and an image display system using the comparator.

2. Related Art

With the coming of digital age, many electronic products must have increased and enhanced functions according to various requirements. If various functions have to be reached, various driving circuits or electrical elements in the electronic product have to be adopted. Hence, a comparator has almost become an indispensable one of the electronic products.

Recently, the comparator has been widely used. Of course, the application to an image display system, such as a flat panel display, is no exception. Generally speaking, the flat panel display has a matrix-type display panel and a driving circuit for driving the matrix-type display panel to display an image. Usually, the comparator is disposed in the driving circuit.

At present, the comparator is frequently implemented by an OP amplifier. Referring to FIG. 1, a conventional comparator 1 has a positive input terminal, a negative input terminal and an output terminal. The negative input terminal receives a data signal V_{d}, and the positive input terminal receives a reference signal Vᵣso that the comparator 1 compares a level of the reference signal Vᵣ with a level of the data signal V_{d}. When the data signal V_{d} is higher than the reference signal Vᵣ, an output signal Vₒ generated at the output terminal of the comparator 1 has a low level; and when the data signal V_{d} is lower than the reference signal Vᵣ, the output signal Vₒ generated at the output terminal has a high level.

However, when the OP amplifier serves as the comparator 1, the power consumption is high and the response time of comparison is also long. In addition, the process variation of the thin film transistor is higher than that of the silicon wafer. Therefore, the property of the OP amplifier manufactured by the thin film transistor tends to be influenced by the manufacturing process so that the comparing precision thereof is deteriorated and the response time and the gain of the comparator 1 are influenced.

Therefore, it is an important subject to provide a comparator and an image display system in order to improve the comparing precision and shorten the response time.

### SUMMARY OF THE INVENTION

In view of the foregoing, the invention is to provide a comparator and an image display system in order to improve the comparing precision and shorten the response time.

To achieve the above, the invention discloses a comparator for comparing a reference signal with a data signal. The comparator includes a voltage boosting circuit, a first logic inverting circuit and a second logic inverting circuit. The voltage boosting circuit receives the reference signal to hold a voltage difference during a first time, and receives the data signal so as to generate a comparing signal according to the data signal and the voltage difference during a second time. The first logic inverting circuit is electrically connected to the voltage boosting circuit for outputting an initial signal to the voltage boosting circuit so as to hold the voltage difference during the first time, and inverts the comparing signal to output a first voltage signal during the second time. The second logic inverting circuit is electrically connected to the first logic inverting circuit during the second time and inverts the first voltage signal so as to output a second voltage signal. The second voltage signal is fed back to hold the comparing signal.

To achieve the above, the invention also discloses an image display system including a matrix-type display panel and a driving circuit for driving the matrix-type display panel. The driving circuit has a comparator for comparing a reference signal with a data signal. The comparator has a first logic inverting circuit, a voltage boosting circuit and a second logic inverting circuit. The voltage boosting circuit receives the reference signal to hold a voltage difference during a first time and receives the data signal to generate a comparing signal according to the data signal and the voltage difference during a second time. The first logic inverting circuit is electrically connected to the voltage boosting circuit, outputs an initial signal to the voltage boosting circuit to hold the voltage difference during the first time, and inverts the comparing signal to output a first voltage signal during the second time. The second logic inverting circuit is electrically connected to the first logic inverting circuit during the second time and inverts the first voltage signal to output a second voltage signal. The second voltage signal is fed back to hold the comparing signal.

As mentioned above, the conventional OP amplifier is replaced with the combination of the first logic inverting circuit, the second logic inverting circuit and the voltage boosting circuit in the comparator and the image display system of the invention. The layout structures of the first logic inverting circuit and the second logic inverting circuit are simpler than that of the OP amplifier, have the advantage of the short response time, and cannot be easily influenced by the manufacturing processes. Thus, the precision of the comparator can be improved.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic illustration showing a conventional comparator;

FIG. 2 is a schematic illustration showing a comparator according to a preferred embodiment of the invention;

FIGS. 3A to 3C are schematic illustrations showing detailed aspects of the comparator of FIG. 2 during a first time and a second time;

FIG. 3D is a schematic illustration showing output-input properties of a first logic inverting circuit according to the preferred embodiment of the invention;

FIG. 4 is a schematic illustration showing a flat panel display according to the preferred embodiment of the invention; and

FIG. 5 is a schematic illustration showing an electronic device according to the preferred embodiment of the invention.

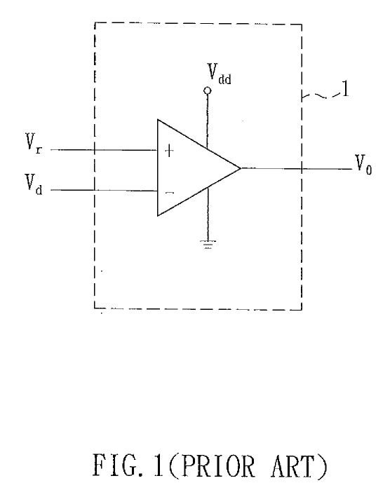

### DETAILED DESCRIPTION OF THE INVENTION

The present invention will be apparent from the following detailed description, which proceeds with reference to the accompanying drawings, wherein the same references relate to the same elements.

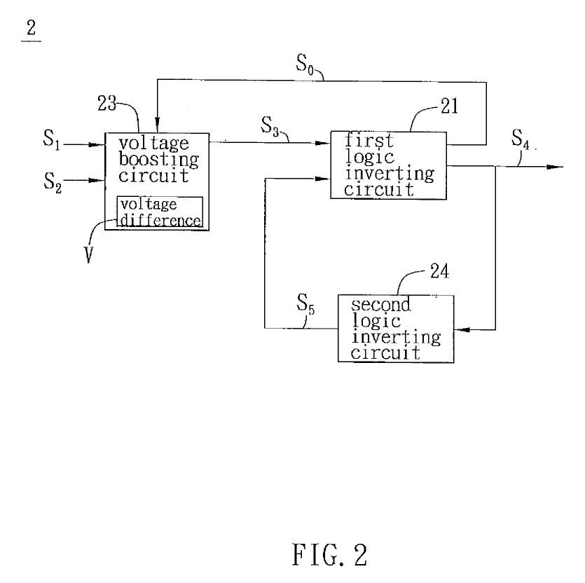

Referring to FIG. 2, a comparator 2 according to a preferred embodiment of the invention is for comparing a reference signal S₁ with a data signal S₂. In the embodiment, the comparator 2 includes a first logic inverting circuit 21, a second logic inverting circuit 24 and a voltage boosting circuit 23.

During a first time, the voltage boosting circuit 23 receives the reference signal S₁ and is electrically connected to the first logic inverting circuit 21, and the first logic inverting circuit 21 outputs an initial signal S₀ to the voltage boosting circuit 23 so that the voltage boosting circuit 23 holds a voltage difference V according to the reference signal S₁ and the initial signal S₀.

During a second time, the voltage boosting circuit 23 receives the data signal S₂ to generate a comparing signal S₃ according to the data signal S₂ and the voltage difference V, and the first logic inverting circuit 21 inverts the comparing signal S₃ to output a first voltage signal S₄. The second logic inverting circuit 24 is electrically connected to the first logic inverting circuit 21 and inverts the first voltage signal S₄ to output a second voltage signal S₅, which is fed back to hold the comparing signal S₃.

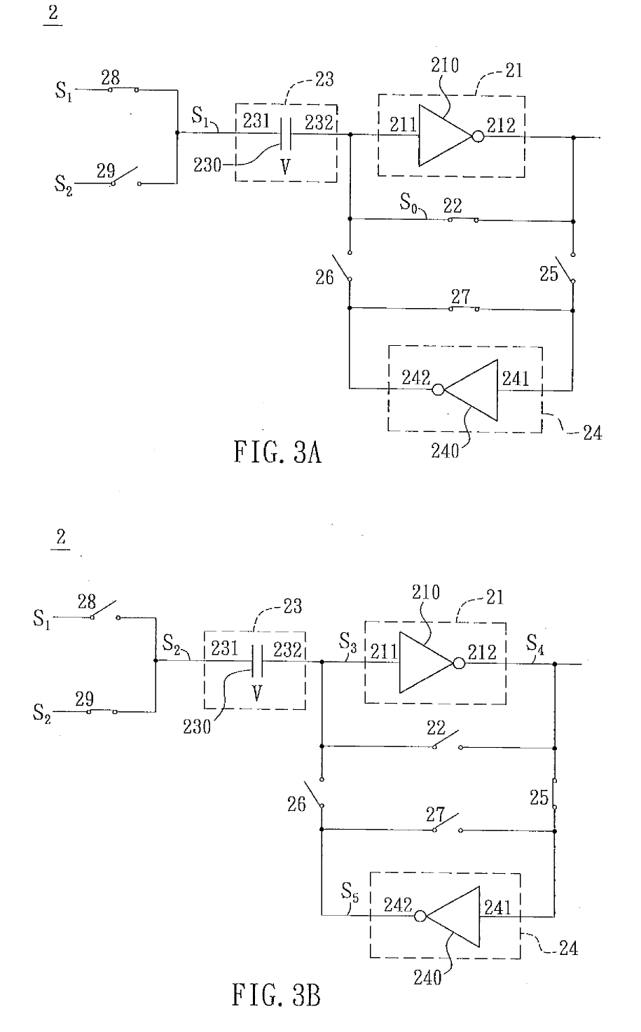

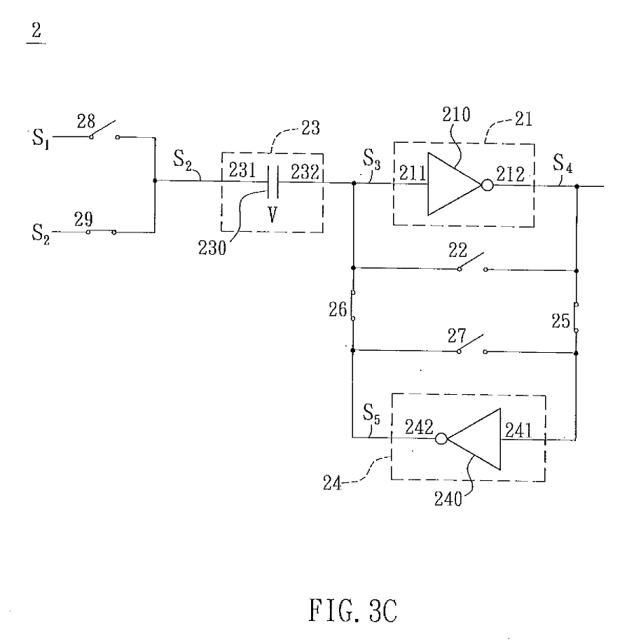

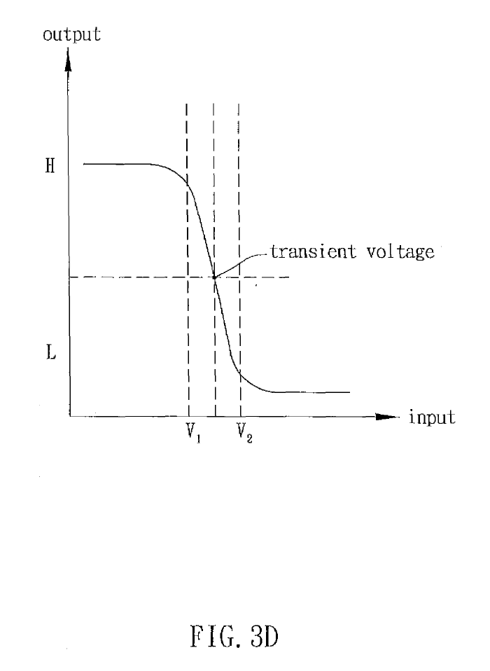

FIGS. 3A to 3C are schematic illustrations showing detailed aspects of the comparator of FIG. 2 during a first time and a second time. As shown in FIG. 3A, the comparator 2 receives the reference signal S₁ from the outside during the first time. As shown in FIG. 3B, the comparator 2 receives the data signal S₂ from the outside during the second time. That is, the reference signal S₁ and the data signal S₂ are inputted to the comparator 2 during different times.

Referring to FIG. 3A, the comparator 2 compares the reference signal S₁ with the data signal S₂, and has the first logic inverting circuit 21, a first switch element 22, the voltage boosting circuit 23, the second logic inverting circuit 24, a second switch element 25, a third switch element 26, a fourth switch element 27, a fifth switch element 28 and a sixth switch element 29.

In the embodiment, the first logic inverting circuit 21 has at least one inverter 210, which has a first input terminal 211 and a first output terminal 212. The first input terminal 211 serves as an input terminal of the first logic inverting circuit 21, and the first output terminal 212 serves as an output terminal of the first logic inverting circuit 21. The second logic inverting circuit 24 has at least one inverter 240, which has a second input terminal 241 and a second output terminal 242. The second input terminal 241 serves as an input terminal of the second logic inverting circuit 24, and the second output terminal 242 serves as an output terminal of the second logic inverting circuit 24. The voltage boosting circuit 23 has at least one capacitor 230, which has a first terminal 231 and a second terminal 232, which respectively serve as two terminals of the voltage boosting circuit 23. In this embodiment, one inverter 210, one inverter 240 and one capacitor 230 are illustrated as an example. To be noted, the numbers of the inverters 210 and 240 and capacitors 230 can be one or more.

In the embodiment, the first terminal 231 of the voltage boosting circuit 23 is electrically connected to the sixth switch element 29 and the fifth switch element 28, and the second terminal 232 is electrically connected to the first input terminal 211 of the first logic inverting circuit 21 and the first switch element 22.

The first switch element 22 is connected to and between the first input terminal 211 and the first output terminal 212 of the first logic inverting circuit 21. The second switch element 25 is connected to and between the first output terminal 212 of the first logic inverting circuit 21 and the second input terminal 241 of the second logic inverting circuit 24. The third switch element 26 is connected to and between the first input terminal 211 of the first logic inverting circuit 21 and the second output terminal 242 of the second logic inverting circuit 24. The fourth switch element 27 is connected to and between the second input terminal 241 and the second output terminal 242. In addition, the property of the second logic inverting circuit 24 is similar to that of the first logic inverting circuit 21, and the possible implementation thereof is also similar to that of the first logic inverting circuit 21.

Referring to FIG. 3A, during the first time, the fifth switch element 28 is turned on to transmit the reference signal S₁ to the voltage boosting circuit 23. The first terminal 231 of the voltage boosting circuit 23 receives the reference signal S₁, which charges/discharges the capacitor 230 of the voltage boosting circuit 23 so that the potential of the first terminal 231 of the voltage boosting circuit 23 is the same as that of the reference signal S₁.

At this time, the first switch element 22 is turned on to electrically connect the first input terminal 211 to the first output terminal 212 of the first logic inverting circuit 21. That is, the first output terminal 212 and the first input terminal 211 of the first logic inverting circuit 21 are short-circuited so that the initial signal S₀ is outputted. In practice, the initial signal S₀ is a transient voltage, as shown in FIG. 3D, so the voltage of the second terminal 232 of the voltage boosting circuit 23 is the same as the transient voltage. In addition, the voltage difference V, which is the potential of the capacitor 230, is generated between the first terminal 231 and the second terminal 232 of the voltage boosting circuit 23 according to the reference signal S₁ and the initial signal S₀.

Meanwhile, the fourth switch element 27 is turned on to electrically connect the second input terminal 241 to the second output terminal 242 of the second logic inverting circuit 24 so that the second output terminal 242 and the second input terminal 241 of the second logic inverting circuit 24 are short-circuited and another transient voltage is obtained. Also, the property of the first logic inverting circuit 21 is the same as that of the second logic inverting circuit 24, so the transient voltage of the second logic inverting circuit 24 is the same as the transient voltage of the first logic inverting circuit 21.

In brief, the comparator 2 makes the output terminals and the input terminals of the first logic inverting circuit 21 and the second logic inverting circuit 24 be short-circuited to reset the voltage of the input terminal during the first time in order to prevent the residual voltages generated before and after the comparison from influencing the present comparing result.

In the embodiment, the first logic inverting circuit 21 and the second logic inverting circuit 24 respectively have the inverters 210 and 240. Please refer to FIG. 3D, which is a schematic illustration showing output-input properties of a first logic inverting circuit according to the preferred embodiment of the invention. Regarding to the general property of the inverter 210/240, the inverter 210/240 outputs a high level when the value of an input voltage is smaller than V₁; otherwise, the inverter 210/240 outputs a low level when the value of the input voltage is greater than V₂. However, when the value of the input voltage ranges between V₁ and V₂, the response of the inverter 210/240 is less sensitive, aid the area is referred to as a transient area of the inverter 210/240. When the output terminal and the input terminal of the inverter 210/240 of the embodiment are respectively electrically connected to each other (i.e., short-circuited), the output terminal and the input terminal of the inverter 210/240 have the same voltage value, which falls within the transient area and is thus referred to as the transient voltage.

In addition, the implementation of each of the first logic inverting circuit 21 and the second logic inverting circuit 24 is not restricted thereto. Instead, each of the first logic inverting circuit 21 and the second logic inverting circuit 24 may be composed of other logic gates. For example, an input of an NAND gate receives a power Vdd and the input signal of this embodiment, and the NAND gate inverts and then outputs the input signal. More specifically, as long as the input-output properties of the logic circuit are similar to those of the inverter, or the logic operation performed by the logic circuit is similar to that of the inverter, the logic circuit may be used to implement the first logic inverting circuit 21 and the second logic inverting circuit 24.

Referring to FIG. 3B, during the second time, the sixth switch element 29 is turned on to transmit the data signal S₂ to the voltage boosting circuit 23, the first terminal 231 of the voltage boosting circuit 23 receives the data signal S₂, and the data signal S₂ charges/discharges the capacitor 230 of the voltage boosting circuit 23 so that the voltage of the first terminal 231 of the voltage boosting circuit 23 is equal to that of the data signal S₂. At this time, the first switch element 22 is not turned on so that the first input terminal 211 and the first output terminal 212 of the first logic inverting circuit 21 are not electrically connected to each other. So, the voltage difference V still exists between the first terminal 231 and the second terminal 232 of the voltage boosting circuit 23, and the second terminal 232 of the voltage boosting circuit 23 generates the comparing signal S₃ according to the data signal S₂ and the voltage difference V.

The first input terminal 211 of the first logic inverting circuit 21 receives the comparing signal S₃. Because the level of the comparing signal S₃ is not held at the transient voltage, the inverter 210 of the first logic inverting circuit 21 inverts the comparing signal S₃ according to the input-output relationship (see FIG. 3D), and generates the first voltage signal S₄ at the first output terminal 212.

The level of the first voltage signal S₄ may really respond with the comparing result between the data signal S₂ and the reference signal S₁, and is determined according to the level difference between the data signal S₂ and the reference signal S₁. When the level of the data signal S₂ is higher than that of the reference signal S₁, the first voltage signal S₄ has the low level; and when the level of the data signal S₂ is lower than the reference signal S₁, the first voltage signal S₄ has the high level.

At this time, the second switch element 25 is turned on to transmit the first voltage signal S₄ to the second input terminal 241 of the second logic inverting circuit 24, and the inverter 240 of the second logic inverting circuit 24 inverts the first voltage signal S₄ to generate the second voltage signal S₅ at the second output terminal 242. The second logic inverting circuit 24 being implemented has an inverter, so the second voltage signal S₅ and the first voltage signal S₄ have inverted levels.

At this time, as shown in FIG. 3C, the third switch element 26 is turned on to make the second voltage signal S₅ be fed back the first input terminal 211 of the first logic inverting circuit 21 to hold the comparing signal S₃. That is, after the comparing result between the data signal S₂ and the reference signal S₁ is generated, the first voltage signal S₄ is inverted into the second voltage signal S₅, which is then fed back to the first input terminal 211 of the first logic inverting circuit 21, through the second logic inverting circuit 24. Accordingly, the level of the first voltage signal S₄ will not be inverted by the fed back voltage signal.

In brief, the comparator 2 respectively makes the output terminals and the input terminals of the first logic inverting circuit 21 and the second logic inverting circuit 24 be short-circuited to reset the voltage of the input terminal during the first time. Thus, it is possible to prevent the residual voltages generated before and after the comparison from influencing the present comparing result. In addition, the transient voltage obtained through the short-circuited condition is about a middle voltage value in an range of output voltages of the first logic inverting circuit 21 and the second logic inverting circuit 24, and the voltage difference V stored at the beginning of the comparison of the voltage boosting circuit 23 is generated according to the transient voltage and the reference signal S₁.

The voltage difference V stored in the voltage boosting circuit 23 will never be changed after the beginning. Therefore, the voltage of the second terminal 232 is changed when the voltage of the first terminal 231 of the voltage boosting circuit 23 is changed. Thus, the comparing result (comparing signal S₃) between the data signal S₂ and the reference signal S₁ may be generated at the second terminal 232 of the voltage boosting circuit 23 during the second time when the voltage boosting technique of the voltage boosting circuit 23 is adopted. In addition, in order to obtain the stable comparing output result, the first logic inverting circuit 21 inverts the comparing signal S₃ and then outputs the first voltage signal S₄ to other application circuits, and the first logic inverting circuit 21 also has the voltage buffering effect.

In addition, the bandwidth of the inverter 210 in the first logic inverting circuit 21 is wider than that of the typical OP amplifier, so the inverter 210 has the shorter response time to thus increase the comparing speed of the comparator 2. On the other hand, as long as the compared input voltage no longer falls within the transient area, the inverters 210 and 240 have the very stable output voltages outside the transient area. Consequently, the drawback of the larger variation in the manufacturing processes of the thin film transistor can be overcome so that the stability of the comparator 2 manufactured according to the manufacturing processes of the thin film transistor can be thus enhanced.

In addition, in order to make the contents of the invention be understood more easily, the comparing approaches of the comparator 2 in FIGS. 3A to 3C will be described according to actual voltage values.

It is assumed that the level of the reference signal S₁ is higher than that of the data signal S₂. For example, the reference signal S₁ is 4 volts and the data signal S₂ is 3 volts. As shown in FIG. 3A during the first time, the voltage of the first terminal 231 of the voltage boosting circuit 23 is set to 4 volts by the reference signal S₁, the first input terminal 211 and the first output terminal 212 of the first logic inverting circuit 21 are electrically connected to each other to generate the transient voltage of 2.5 volts. Thus, the voltage of the second terminal 232 of the voltage boosting circuit 23 is set to 2.5 volts by the transient voltage so that the voltage difference V generated between the first terminal 231 and the second terminal 232 of the voltage boosting circuit 23 is 1.5 volts, which is equal to the potential of the capacitor 230. On the other hand, the second input terminal 241 and the second output terminal 242 of the second logic inverting circuit 24 are electrically connected to each other to generate the transient voltage of 2.5 volts.

Then, as shown in FIG. 3B during the second time the voltage of the first terminal 231 of the voltage boosting circuit 23 is set to 3 volts by the data signal S₂. Because the voltage boosting circuit 23 still stores the voltage difference V of 1.5 volts, the comparing signal S₃ of 1.5 volts is generated at the second terminal 232 of the voltage boosting circuit 23 according to the voltage difference V of 1.5 volts and the data signal S₂ of 3 volts. The first logic inverting circuit 21 inverts the comparing signal S₃ of 1.5 volts and then outputs the first voltage signal S₄ having the steady-state high level, and the second logic inverting circuit 24 inverts the first voltage signal S₄ and then generates the low-level second voltage signal S₅ at the second output terminal 242.

Next, as shown in FIG. 3C, the low-level second voltage signal S₅ is fed back to the first input terminal 211 of the first logic inverting circuit 21 to thus hold the comparing signal S₃ at the low level and ensure the level of the first voltage signal S₄ to be continuous high without inversion.

In addition, it is assumed that the level of the reference signal S₁ is lower than that of the data signal S₂. For example, the reference signal S₁ is 4 volts and the data signal S₂ is 5 volts. The comparing signal S₃ is boosted to 3.5 volts during the second time. Thus, the first logic inverting circuit 21 inverts the comparing signal S₃ and then obtains the low-level first voltage signal S₄ to serve as an output. Thereafter, the second logic inverting circuit 24 inverts the first voltage signal S₄ to generate the high-level second voltage signal S₅, and the second voltage signal S₅ can hold the comparing signal S₃ at the high level to ensure the level of the first voltage signal S₄ to be continuous low without inversion.

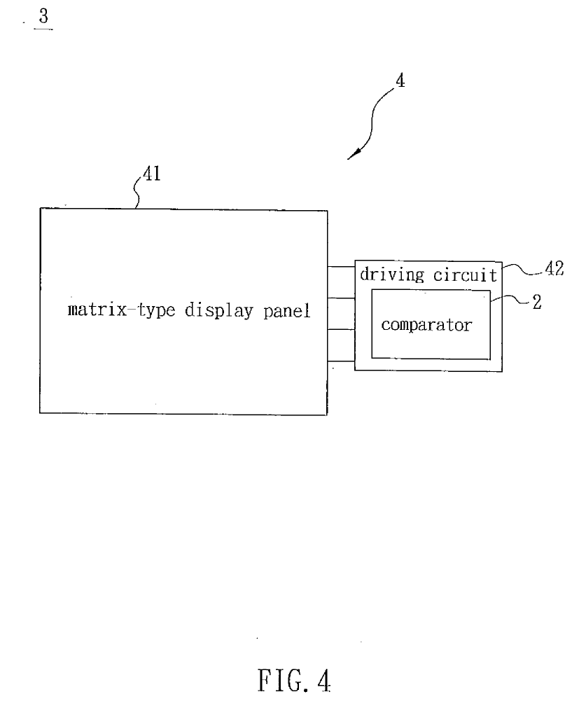

The comparator 2 of this embodiment may be applied to various electronic devices or an image display system, such as a flat panel display. Referring to FIG. 4, an image display system 3 in another embodiment has a flat panel display 4, which includes a matrix-type display panel 41 and a driving circuit 42 for driving the matrix-type display panel 41. A plurality of comparators 2 is integrated in the driving circuit 42. The structure, function and features of each of these comparators 2 is the same as those of the comparator 2 according to the above-mentioned embodiment of the invention, so detailed descriptions thereof will be omitted. Usually, the driving circuit 42 includes a column driver and a row driver, which includes a digital-to-analog converter. The comparator 2 may be applied to the digital-to-analog converter.

In this embodiment, the matrix-type display panel 41 may be an organic light-emitting diode (LED) panel, or a twisted nematic LCD panel, a multi-domain vertical alignment (MVA) LCD panel, an in-plane switching (IPS) LCD panel, a fringe-field switching (FFS) LCD panel, a transmissive LCD panel, a reflective LCD panel, a transflective LCD panel or a low temperature polysilicon (LTPS) LCD panel.

Taking the LTPS LCD panel as an example, the driving circuit 42 may be partially or entirely integrated on the substrate of the matrix-type display panel 41. If a portion of the driving circuit 42 is integrated in the matrix-type display panel 41, the other portion of the driving circuit 42 still has to be connected to the matrix-type display panel 41 through various types of connection cables, such as a flexible circuit cable. If the driving circuit 42 is entirely integrated in the matrix-type display panel 41, it is the aspect of the system on glass (SOG).

In addition, if the matrix-type display panel 41 is not self-emissive or needs an active light source, a backlight module (not shown) has to be disposed in the flat panel display 4 to serve as a light source for providing light rays to the matrix-type display panel 41 to display an image.

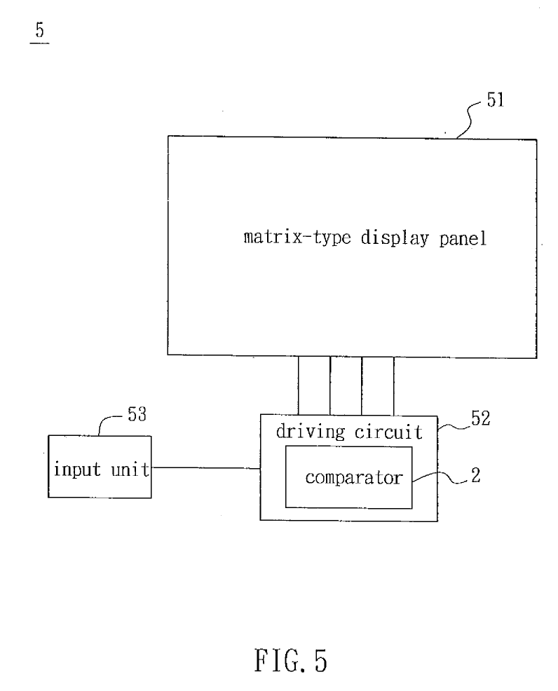

Referring to FIG. 5, an electronic device 5 according to the embodiment of the invention includes a matrix-type display panel 51, a driving circuit 52 and an input unit 53. The matrix-type display panel 51 and the driving circuit 52 are respectively the same as the matrix-type display panel 41 and the driving circuit 42 in the above-mentioned embodiment. The driving circuit 52 drives the matrix-type display panel 51 to display an image. The input unit 53 is coupled to the driving circuit 52 and provides an input to the driving circuit 52 to make the matrix-type display panel 51 display the image or data specified by the input unit 53. In the embodiment, the electronic device 5 may be a mobile phone, a digital camera, a personal digital assistant, a notebook computer, a desktop computer, a television, a vehicle display, a head mounted display, a printer screen, a MP3 player, a hand-held game console or a portable DVD player.

In summary, the conventional OP amplifier is replaced with the combination of the first logic inverting circuit, the second logic inverting circuit and the voltage boosting circuit in the comparator and the image display system of the invention. The layout structures of the first logic inverting circuit and the second logic inverting circuit are simpler than that of the OP amplifier, have the advantage of the short response time, and cannot be easily influenced by the manufacturing processes. Thus, the precision of the comparator can be improved.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A comparator for comparing a reference signal with a data signal, comprising:
a voltage boosting circuit for receiving the reference signal to hold a voltage difference during a first time, and receiving the data signal to generate a comparing signal according to the data signal and the voltage difference during a second time;
a first logic inverting circuit electrically connected to the voltage boosting circuit for outputting an initial signal to the voltage boosting circuit so as to hold the voltage difference during the first time, and inverting the comparing signal to output a first voltage signal during the second time; and
a second logic inverting circuit electrically connected to the first logic inverting circuit during the second time and inverting the first voltage signal so as to output a second voltage signal, wherein the second voltage signal is fed back to hold the comparing signal.

2. The comparator according to claim 1, wherein the first logic inverting circuit has a first input terminal and a first output terminal, the first input terminal is electrically connected to the voltage boosting circuit, and the first input terminal is electrically connected to the first output terminal to output the initial signal to the voltage boosting circuit to hold the voltage difference during the first time.

3. The comparator according to claim 2, further comprising:
a first switch element, wherein the first switch element is turned on to electrically connect the first input terminal of the first logic inverting circuit to the first output terminal of the first logic inverting circuit during the first time.

4. The comparator according to claim 2, wherein the second logic inverting circuit has a second input terminal and a second output terminal, the second input terminal is electrically connected to the second output terminal during the first time, and the second input terminal is electrically connected to the first output terminal to invert the first voltage signal so as to output the second voltage signal during the second time.

5. The comparator according to claim 4, further comprising:
a second switch element, wherein the second switch element is turned on to electrically connect the first output terminal of the first logic inverting circuit to the second input terminal of the second logic inverting circuit during the second time.

6. The comparator according to claim 5, further comprising:
a third switch element, wherein the third switch element is turned on to electrically connect the second output terminal of the second logic inverting circuit to the first input terminal of the first logic inverting circuit after the second switch element is turned on.

7. The comparator according to claim 4, further comprising:
a fourth switch element, wherein the fourth switch element is turned on to electrically connect the second input terminal of the second logic inverting circuit to the second output terminal of the second logic inverting circuit during the first time.

8. The comparator according to claim 1, wherein the voltage boosting circuit has a first terminal and a second terminal, the second terminal is electrically connected to the first logic inverting circuit, the first terminal receives the reference signal to hold the voltage difference between the first terminal and the second terminal during the first time, and the first terminal receives the data signal during the second time so that the comparing signal is generated at the second terminal according to the data signal and the voltage difference.

9. The comparator according to claim 8, further comprising:
a fifth switch element, wherein the fifth switch element is turned on to transmit the reference signal to the first terminal of the voltage boosting circuit during the first time; and
a sixth switch element, wherein the sixth switch element is turned on to transmit the data signal to the first terminal of the voltage boosting circuit during the second time.

10. The comparator according to claim 1, wherein the first voltage signal has a low level when a level of the data signal is higher than that of the reference signal, and the first voltage signal has a high level when the level of the data signal is lower than that of the reference signal.

11. The comparator according to claim 1, wherein the second logic inverting circuit comprises at least one logic gate.

12. The comparator according to claim 1, wherein the second logic inverting circuit comprises at least one inverter.

13. The comparator according to claim 1, wherein the first logic inverting circuit comprises at least one logic gate.

14. The comparator according to claim 1, wherein the first logic inverting circuit comprises at least one inverter.

15. The comparator according to claim 1, wherein the voltage boosting circuit comprises at least one capacitor.

16. An image display system, comprising:
a matrix-type display panel; and
a driving circuit for driving the matrix-type display panel, wherein the driving circuit has a comparator for comparing a reference signal with a data signal, the comparator has a first logic inverting circuit, a voltage boosting circuit and a second logic inverting circuit, the voltage boosting circuit receives the reference signal to hold a voltage difference during a first time and receives the data signal to generate a comparing signal according to the data signal and the voltage difference during a second time, the first logic inverting circuit is electrically connected to the voltage boosting circuit, outputs an initial signal to the voltage boosting circuit to hold the voltage difference during the first time, and inverts the comparing signal to output a first voltage signal during the second time, the second logic inverting circuit is electrically connected to the first logic inverting circuit during the second time and inverts the first voltage signal to output a second voltage signal, and the second voltage signal is fed back to hold the comparing signal.

17. The image display system according to claim 16, further comprising:
a flat panel display having the matrix-type display panel and the driving circuit.

18. The image display system according to claim 16, further comprising:
an electronic device having the matrix-type display panel, the driving circuit and an input unit, wherein the input unit is coupled to the driving circuit and provides an input to the driving circuit to drive the matrix-type display panel to display an image.

19. The image display system according to claim 18, wherein the electronic device is a mobile phone, a digital camera, a personal digital assistant, a notebook computer, a desktop computer; a television, a vehicle display, a head mounted display, a printer screen, a MP3 player, a hand-held game console or a portable DVD player.

20. The image display system according to claim 16, wherein the voltage boosting circuit comprises at least one capacitor.
